(19) United States
(12) Patent Application Publication
(10) Pub. No.: US 2012/0049291 A1
(43) Pub. Date: Mar. 1, 2012

(54) Polysilicon Resistors Formed in a Semiconductor Device Comprising High-K Metal Gate Electrode Structures

(75) Inventors: Thilo Scheiper, Dresden (DE); Steven Langdon, Dresden (DE)

(73) Assignee: GLOBALFOUNDRIES INC., Grand Cayman (KY)

(21) Appl. No.: 13/185,040

(22) Filed: Jul. 18, 2011

(30) Foreign Application Priority Data
Aug. 31, 2010 (DE) 10 2010 040 058.0

(51) Int. Cl. H01L 27/06; H01L 21/02; H01L 21/8234

(52) U.S. Cl. 257/380; 438/384; 438/385; 257/E27.016; 257/E21.004; 257/E21.616

(57) ABSTRACT

In sophisticated semiconductor devices, resistors may be provided together with high-k metal gate electrode structures by using a polycrystalline silicon material without requiring a deterioration of the crystalline nature and thus conductivity of a conductive metal-containing cap material that is used in combination with the high-k dielectric gate material. In this manner, superior uniformity of the resistance values may be obtained, while at the same time reducing the overall process complexity.

### BACKGROUND OF THE INVENTION

1. Field of the Invention

The present disclosure generally relates to the field of fabricating integrated circuits, and, more particularly, to resistors in complex integrated circuits that comprise metal gate electrode structures.

2. Description of the Related Art

In modern integrated circuits, a very high number of individual circuit elements, such as field effect transistors in the form of CMOS, NMOS, PMOS elements, are formed on a single chip area. Typically, feature sizes of these circuit elements are decreased with the introduction of every new circuit generation, to provide currently available integrated circuits with high performance in terms of speed and/or power consumption. A reduction in size of transistors is an important aspect in steadily improving device performance of complex integrated circuits, such as CPUs. The reduction in size commonly brings about an increased switching speed, thereby enhancing signal processing performance.

In addition to the large number of transistor elements, a plurality of passive circuit elements, such as capacitors and resistors, are typically formed in integrated circuits as required by the basic circuit layout. Due to the decreased dimensions of circuit elements, not only the performance of the individual transistor elements may be improved, but also their packing density may be significantly increased, thereby providing the potential for incorporating increased functionality into a given chip area. For this reason, highly complex circuits have been developed, which may include different types of circuits, such as analog circuits, digital circuits and the like, thereby providing entire systems on a single chip (SOC).

Although transistor elements are the dominant circuit element in highly complex integrated circuits and substantially determine the overall performance of these devices, the passive components, such as the resistors, may also strongly influence the overall device performance, wherein the size of these passive circuit elements may also have to be adjusted with respect to the scaling of the transistor elements in order to not unduly consume valuable chip area. Moreover, the passive circuit elements, such as the resistors, may have to be provided with a high degree of accuracy in order to meet tightly set margins according to the basic circuit design. For example, even in substantially digital circuit designs, corresponding resistance values may have to be provided within tightly set tolerance ranges so as to not unduly contribute to operational instabilities and/or increased signal propagation delay. For example, in sophisticated applications, resistors may frequently be provided in the form of “integrated polysilicon” resistors which may be formed above isolation structures so as to obtain the desired resistance value without significantly contributing to parasitic capacitance, as may be the case in “buried” resistive structures which may be formed within the active semiconductor layer. A typical polysilicon resistor may thus require the deposition of the basic polysilicon material, which may frequently be combined with the deposition of a polysilicon gate electrode material for the transistor elements. During the patterning of the gate electrode structures, also the resistors are formed, the size of which may significantly depend on the basic specific resistance value of the polysilicon material and the type of dopant material and concentration that may be incorporated into the resistors so as to adjust the resistance values. Since typically the resistance value of doped polysilicon material may be a non-linear function of the dopant concentration, typically, specific implantation processes are required, independent of any other implantation sequences for adjusting the characteristics of the polysilicon material of the gate electrodes of the transistors.

Moreover, the continuous drive to shrink the feature sizes of complex integrated circuits has resulted in a gate length of field effect transistors of approximately 50 nm and less. A field effect transistor, irrespective of whether an N-channel transistor or a P-channel transistor is considered, typically comprises so-called “PN junctions,” that are formed by an interface of highly doped regions, referred to as drain and source regions, with a slightly doped or non-doped region, referred to as a channel region, that is disposed adjacent to the highly doped regions. In a field effect transistor, the conductivity of the channel region, i.e., the drive current capability of the conductive channel, is controlled by a gate electrode formed adjacent to the channel region and separated therefrom by a thin insulating layer. The conductivity of the channel region, upon forming a conductive channel due to the application of an appropriate control voltage to the gate electrode, depends on the dopant concentration of the drain and source regions, the mobility of the charge carriers and, for a given transistor width, on the distance between the source region and the drain region, which is also referred to as channel length.

Presently, most complex integrated circuits are based on silicon due to the substantially unlimited availability, the well-understood characteristics of silicon and related materials and processes, and due to the experience gathered during the last 50 years. Therefore, silicon will likely remain the material of choice for future circuit generations. One reason for the important role of silicon for the fabrication of semiconductor devices has been the superior characteristics of a silicon/silicon dioxide interface that allows a reliable electrical insulation of different regions from each other. The silicon/silicon dioxide interface is stable at high temperatures and, thus, allows high temperature processes to be performed, as are typically required for anneal processes in order to activate dopants and to cure crystal damage without sacrificing the electrical characteristics of the interface. Consequently, in field effect transistors, silicon dioxide has been preferably used as a base material for gate insulation layers which separate the gate electrode, frequently comprised of polysilicon, from the silicon channel region. Upon further device scaling, however, the reduction of channel length may require a corresponding adaptation of the thickness of the silicon dioxide-based gate dielectric in order to substantially avoid a so-called “short channel” behavior, according to which variability in channel length may have a significant influence on the resulting threshold voltage of the transistor. Aggressively scaled transistor devices with a relatively low supply voltage and, thus, a reduced threshold voltage, therefore, suffer from a significant increase of the leakage current caused by the reduced thickness of a silicon dioxide gate dielectric.

For this reason, replacing silicon dioxide as the material for gate insulation layers has been considered, particularly for highly sophisticated applications. Possible alternative materials include such materials that exhibit a significantly higher permittivity, so that a physically greater thickness of a correspondingly formed gate insulation layer provides a capacitive coupling that would be obtained by an extremely thin silicon dioxide layer. It has been suggested to replace silicon dioxide with high permittivity materials, such as tantalum oxide, strontium titanium oxide, hafnium oxide, hafnium silicon oxide, zirconium oxide and the like.

Additionally, transistor performance may further be increased by providing an appropriate conductive material for the gate electrode in order to replace the usually used polysilicon material, since polysilicon may suffer from charge carrier depletion at the vicinity of the interface positioned between the gate dielectric material and the polysilicon material, thereby reducing the effective capacitance between the channel region and the gate electrode during transistor operation. Thus, a gate stack has been suggested in which a high-k dielectric material provides enhanced capacitance, while additionally maintaining any leakage currents at an acceptable level. Since the non-polysilicon material, such as titanium nitride, may be formed such that it may directly be in contact with gate dielectric material, the presence of a depletion zone may thus be avoided, while, at the same time, a moderately high conductivity is achieved.

As is well known, the threshold voltage of the transistor may depend on the overall transistor configuration, on a complex lateral and vertical dopant profile of the drain and source regions, and the corresponding configuration of the PN junctions, and on the work function of the gate electrode material. Consequently, in addition to providing the desired dopant profiles, the work function of the metal-containing gate electrode material also has to be appropriately adjusted with respect to the conductivity type of the transistor under consideration. For this reason, typically, metal-containing electrode materials may be used for N-channel transistors and P-channel transistors, which may be provided according to well-established manufacturing strategies in a very advanced manufacturing stage.

In some of these so-called replacement gate approaches, the high-k dielectric material may be formed in combination with a titanium nitride cap material, which may thus be used as an efficient material for confining the sensitive high-k material and providing a moderately high conductive material layer in close proximity to the gate dielectric material. Thereafter, silicon in an amorphous state is provided so as to act as a placeholder material since the amorphous silicon material may be replaced in a very advanced manufacturing stage. The resulting layer stack in combination with any additional sacrificial materials, such as dielectric cap materials and the like, may then be patterned into a gate electrode structure. Concurrently, the corresponding resistors are formed as described above. Subsequently, any further processes are performed in order to complete the basic transistor configuration by forming drain and source regions, performing anneal processes and finally embedding the transistors and also the resistors in a dielectric material. Consequently, after any high temperature anneal processes, an appropriate material removal sequence may be applied in order to expose the placeholder silicon material, which may then be removed in the gate electrode structures on the basis of highly selective etch processes. Based on an appropriate masking regime, thereafter, appropriate metal-containing electrode materials are filled into the gate electrode structures of N-channel transistors and P-channel transistors in order to adjust the required work function for these different types of transistors. Moreover, a highly conductive electrode metal, such as aluminum and the like, may be filled into the gate electrode structures. In this manner, superior gate conductivity and the desired high degree of channel controllability may be achieved. Furthermore, the work function may be adjusted, for instance, by providing appropriate metal species, wherein any drift in transistor characteristics may be substantially eliminated since any high temperature processes have been performed in the earlier manufacturing phase. In this patterning regime, the resistive structures may also receive the electrode metal, thereby imparting superior conductivity to the resistive structures, which, however, may thus reduce the resistance value, thereby requiring a reduction in line width of the resistors and/or an increase of the total length of the resistors. While the former measure may result in patterning problems since extremely small line widths have to be provided, the latter aspect may result in increased area consumption in the semiconductor die.

For these reasons, it has been proposed to remove the amorphous silicon material selectively from the gate electrode structures and preserving the silicon material in the resistors by appropriate masking regimes and the like. Although the resistance value may be significantly reduced upon preserving the amorphous silicon material, it has nevertheless been recognized that the resulting resistivity may still require significant redesigns of silicon-based resistors when formed in accordance with the above-described replacement gate approaches.

Similarly, in other metal gate approaches, the gate electrode structures are completed in an early manufacturing stage in order to avoid the complex process steps for replacing the amorphous silicon material and providing appropriate work function adjusting metal species and the highly conductive gate metal. To this end, the gate dielectric material comprising the high-k component may be deposited in combination with appropriate conductive material which may comprise specifically selected work function metal species, such as lanthanum, aluminum and the like, which may be provided as dedicated material layers and/or which may be diffused into the underlying gate dielectric material. Thereafter, an appropriate metal-containing electrode material, for instance in the form of titanium nitride, followed by the deposition of amorphous silicon in combination with any appropriate sacrificial materials and the like. Thereafter, the gate electrodes are patterned together with the resistors, as is also described above, and the further processing is continued by forming the transistors using any appropriate process strategy. In a final stage of the overall process flow, metal silicide may be formed in the transistors and also in the silicon-containing gate electrodes and in corresponding contact areas of the resistors, thereby completing the basic transistor configuration.

Although in this case the resistors are provided on the basis of amorphous silicon, similarly as described above for the latter replacement gate approaches, it turns out that the general resistance values may still be too high, thereby requiring significant redesigns. It has been recognized that, for example, using amorphous silicon, the finally obtained resistance value of the resistors is substantially determined by the titanium nitride material formed above the high-k dielectric material. Consequently, in some conventional approaches, it has been proposed to reduce the sheet resistance of the titanium nitride material selectively for the resistors by significantly modifying the crystalline state of the titanium nitride material after forming the gate electrode structures. To this end, implantation techniques are applied in which a heavy implantation species, such as xenon, is implanted during a masked implantation process in order to substantially amorphize or at least create heavy damage in the titanium nitride material. Although the resulting sheet resistance is significantly higher, it turns out, however, that a significant variation of the resistance values may occur. It is believed that even slight variations of the thickness upon depositing the amorphous silicon material may result in significant differences in the degree of modification of the crystalline status of the titanium nitride material during the masked amorphization implantation process. Consequently, significant variations in device performance may be observed, even if substantially digital circuits are considered, since also in these cases precise resistance values may be required.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure provides semiconductor devices and manufacturing techniques in which silicon-based resistors may be provided in combination with high-k metal gate electrode structures, wherein the required resistance values may be achieved with superior uniformity and reduced process complexity. In the context of the complex manufacturing strategy for providing high-k metal gate electrode structures, for instance in a process technique in which the gate electrode structures may be completed in an early manufacturing stage, it has been state of the art to use amorphous silicon material, in particular as amorphous silicon material is considered as providing a higher sheet resistance compared to, for instance, polycrystalline silicon material. As discussed above, although amorphous silicon material is typically used, the resulting resistance values for silicon-based resistors have been found to be too high since the main part of the resistance value is contributed by the titanium nitride material. According to the principles disclosed herein, it has surprisingly been discovered that the usage of polycrystalline silicon for the resistor materials may result in a resistance value that may be appropriately adjusted on the basis of the polycrystalline silicon material, for instance by implantation and the like, without requiring any specific modification and, in particular, a destruction of the crystalline status of the conductive cap material formed above the gate dielectric material including the high-k component. Consequently, due to this finding, silicon-based resistors may be efficiently provided without significant redesign, while at the same time eliminating the need for additional lithography steps and implantation processes, which are conventionally applied for deteriorating the crystalline status of the conductive cap material. In particular, using a modified titanium nitride-based material may provide superior resistance values of the polycrystalline silicon resistors. For example, in a titanium aluminum nitride material, a fraction of at least one atomic percent aluminum and higher may result in appropriate resistance values.

One illustrative semiconductor device disclosed herein comprises a transistor comprising a gate electrode structure. The gate electrode structure comprises a first stack of material layers that comprises a high-k dielectric material and a metal-containing electrode material formed above the high-k dielectric material. The semiconductor device further comprises a resistor comprising a second stack of material layers which comprises the high-k dielectric material, the metal-containing electrode material and a polysilicon electrode material formed above the metal-containing electrode material. Furthermore, the crystalline structure of the metal-containing electrode material is substantially identical in the first and second stacks of material layers.

One illustrative method disclosed herein relates to forming a resistive structure of a semiconductor device. The method comprises forming an insulating material layer above a first device region and a second device region, wherein the insulating material layer comprises a high-k dielectric material. The method further comprises forming a titanium and nitrogen-containing conductive material layer above the insulating material layer. Additionally, the method comprises forming a polycrystalline silicon layer on the titanium and nitrogen-containing conductive material layer. Furthermore, the method comprises forming a gate electrode structure of a transistor above the first device region and forming a resistor structure above the second device region of the semiconductor device, wherein the gate electrode structure and the resistor structure comprise the insulating material layer, the titanium and nitrogen-containing conductive layer and the polycrystalline silicon layer.

A further illustrative method disclosed herein comprises forming a resistive structure above an isolation structure of a semiconductor device, wherein the resistive structure comprises a polycrystalline semiconductor material formed above a high-k dielectric material and a metal-containing cap layer. The method further comprises adjusting a resistance of the resistive structure without deteriorating a crystalline state of the metal-containing cap layer.

### BRIEF DESCRIPTION OF THE DRAWINGS

The disclosure may be understood by reference to the following description taken in conjunction with the accompanying drawings, in which like reference numerals identify like elements, and in which:

FIG. 1a schematically illustrates a cross-sectional view of a semiconductor device in an early manufacturing stage for forming a high-k metal gate electrode structure and a semi-conductor-based resistor, according to illustrative embodiments;

FIG. 1b schematically illustrates the semiconductor device in a further advanced manufacturing stage in which a gate electrode structure is formed above an active region and a resistor is formed above an isolation region, wherein a metal-containing cap material may have substantially the same crystalline status in the gate electrode structure and the resistor, according to illustrative embodiments;

FIG. 1c schematically illustrates a cross-sectional view of the semiconductor device in a further advanced manufacturing stage in which the transistor and the resistor are illustrated after any high temperature anneal processes, according to illustrative embodiments; and

FIG. 1d schematically illustrates a cross-sectional view of the semiconductor device according to illustrative embodiments in which the silicon material may be selectively removed from the gate electrode structure according to a replacement gate approach.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure generally addresses the problem of providing semiconductor-based resistors, in particular silicon-based resistors in the context of a complex manufacturing regime in which high-k metal gate electrode structures are to be provided. To this end, it has been recognized that surprisingly a polycrystalline semiconductor material, and in particular a polycrystalline silicon material hereinafter also referred to as polysilicon, may be used in combination with titanium nitride-based conductive cap layers without requiring a deterioration of the crystalline state of this material, while nevertheless enabling an efficient adjustment of the resistance values of the polysilicon resistors. It has been found that, for otherwise identical device and process parameters, the usage of polysilicon in combination with titanium nitride and in particular in combination with aluminum-containing titanium nitride, which may also be referred to herein as titanium aluminum nitride, may result in resistance values that are approximately 20 percent or even more different compared to the amorphous silicon/titanium nitride combination, thereby indicating that polysilicon is a main contributor to the overall resistance value. Consequently, an efficient adjustment may be accomplished on the basis of the polysilicon material, thereby enabling the provision of the required resistance values of the polysilicon resistors. In conventional approaches, the amorphous silicon material may not allow an efficient adjustment since the main contribution of the resistance value stems from the titanium nitride material, thereby requiring a significant reduction of its conductivity.

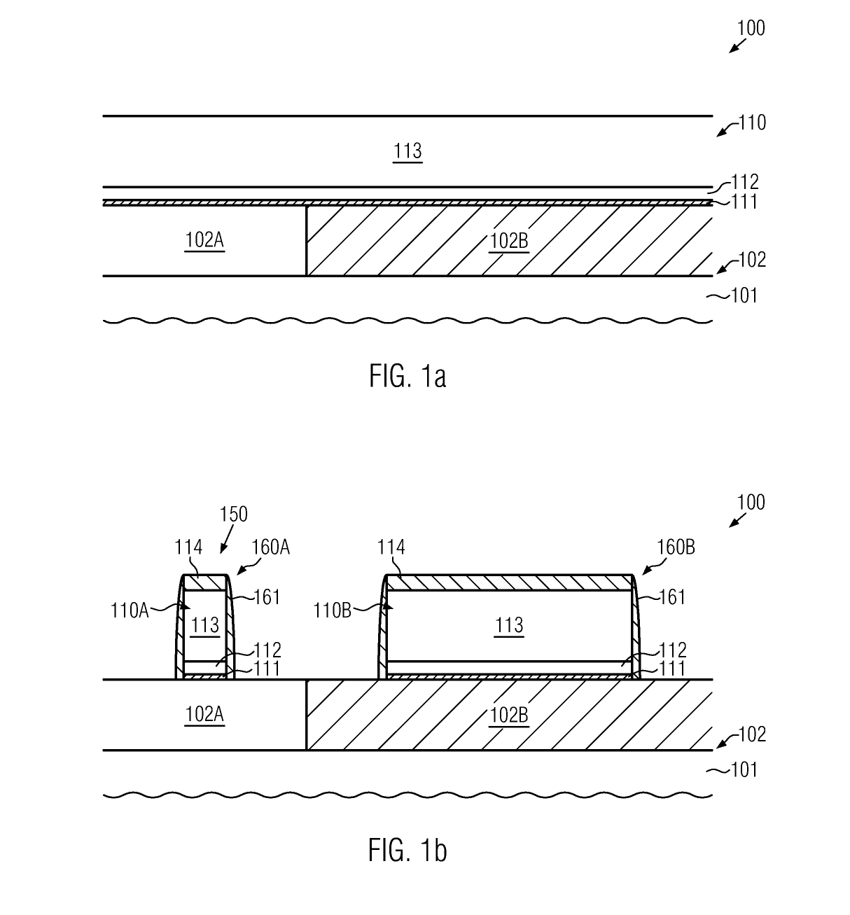

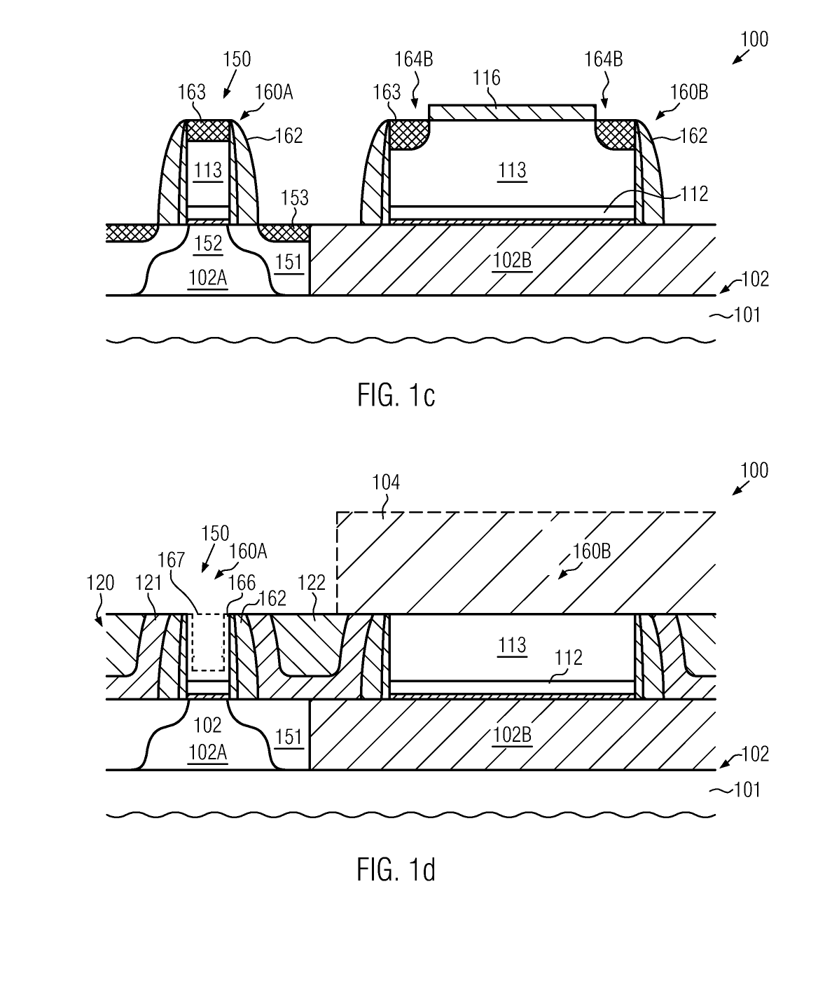

FIG. 1a schematically illustrates a cross-sectional view of a semiconductor device 100 in an early manufacturing stage. As illustrated, the semiconductor device 100 may comprise a substrate 101 and a semiconductor layer 102 formed thereon, wherein the substrate 101 and the semiconductor layer 102 may form a “bulk” configuration when the semiconductor layer 102 may directly connect to a crystalline material of the substrate 101. In other cases, a silicon-on-insulator (SOI) configuration may be provided by providing a buried insulating layer (not shown) directly below the semiconductor layer 102. It should be appreciated that the semiconductor layer 102 may represent a semiconductor material in an initial state whereas, during the further processing, any non-semiconductor material areas may be formed therein. For example, the semiconductor layer 102 may have formed therein a plurality of active regions, i.e., of semiconductor regions, in and above which transistors are to be formed. For convenience, a single active region 102A is illustrated in FIG. 1a. Similarly, the layer 102 may comprise isolation regions, such as an isolation region 102B, which may laterally delineate active regions and which may also provide areas for forming thereon resistive structures and the like. In this case, the isolation structure 102B may be considered as a device region above which is to be provided a resistor or resistive structure, as will be described later on. Furthermore, in this sense, the active region 102A may be considered as a further device region in and above which a transistor is to be formed. Moreover, in the manufacturing stage shown, a stack of material layers 110 is provided above the regions 102A, 102B and may comprise an insulating layer 111 and a conductive metal-containing cap layer 112 in combination with a polycrystalline semiconductor material 113, which in one illustrative embodiment is a polycrystalline silicon material. In other cases, the semiconductor material 113 may also comprise a certain amount of germanium, if considered appropriate. The insulating layer 111 may comprise a high-k dielectric material, such as hafnium oxide, hafnium silicon oxide, zirconium oxide and the like, in order to endow the layer 111 with an increased dielectric constant at an acceptable thickness, which may be 1.5 nm and more, thereby keeping any leakage currents at an acceptable level. For example, the insulating layer 111 may comprise a conventional dielectric material, for instance in the form of silicon dioxide, silicon oxynitride and the like, with a thickness of 1 nm and significantly less in combination with a specific high-k dielectric material layer. Furthermore, the conductive cap material 112 may comprise titanium and nitrogen, which may also be referred to herein as titanium nitride, while, in other illustrative embodiments, the layer 112 may comprise, in addition to titanium and nitrogen, also a certain amount of aluminum, for instance one atomic percent or more, so as to form a titanium aluminum nitride material layer. A thickness of the layer 112 may typically be selected in the range of 5-20 nm, depending on the overall device and process requirements. The polycrystalline layer 113 may be provided with an appropriate basic doping concentration or may be provided as a substantially non-doped silicon material or silicon/germanium material with a thickness in accordance with ion blocking capabilities, overall conductivity and the like.

The semiconductor device 100, as illustrated in FIG. 1a, may be formed on the basis of the following processes. The active region 102A may be defined in lateral size, shape and position by forming the isolation structure 102B, which may be accomplished on the basis of sophisticated lithography, etch, deposition and planarization techniques. Prior to or after providing the isolation structure 102B, the basic dopant concentration or well doping may be implemented in the active region 102A by using well-established implantation processes and masking regimes. Thereafter, the insulating layer 111 may be formed, for instance, by oxidation, when a basic oxide material may be required, by deposition, for instance for providing a silicon dioxide base material using deposition techniques and providing a high-k dielectric material, which may be accomplished on the basis of chemical vapor deposition (CVD), atomic layer deposition (ALD) and the like. Thereafter, specific materials may be applied, depending on the overall process strategy, in order to define an appropriate work function for various types of transistors. To this end, appropriate metal layers, such as lanthanum, aluminum and the like, possibly in combination with titanium nitride, may be deposited and may be appropriately patterned so as to diffuse the appropriate work function species into the underlying insulating material 111. In some approaches, these material layers may be removed and the conductive cap material 112 may be deposited as an electrode material by using well-established sputter deposition techniques and the like. It should be appreciated that, in other cases, corresponding dedicated thin material layers, for instance a lanthanum layer, an aluminum layer and the like, provided prior to depositing the cap layer 112, may be preserved throughout the further processing. In this case, any such dedicated work function adjusting metal layers may be considered as being a part of the cap layer 112. In some illustrative embodiments, the deposition of the layer 112 in the form of a titanium nitride material may involve the incorporation of an aluminum species in order to provide a titanium aluminum nitrogen compound, which may also be referred to as titanium aluminum nitride material. In this case, the titanium contents and the aluminum contents may be at least one atomic percent and more, preferably several atomic percent. A corresponding titanium aluminum nitride material may be provided on the basis of sputter deposition and the like. Thereafter, the polycrystalline semiconductor material, such as the silicon material or the silicon/germanium material, may be deposited on the basis of low pressure CVD, thereby forming the material with a polycrystalline state above the layer 112. To this end, any well-established recipes for providing polycrystalline silicon or silicon/germanium material may be used.

FIG. 1b schematically illustrates the semiconductor device 100 in a further advanced manufacturing stage. As illustrated, a gate electrode structure 160A of a transistor 150 may be formed above the active region 102A and may comprise the material layers 111, 112 and 113. Similarly, a resistor or resistive structure 160B may be formed above the isolation region 102B and may also comprise the layers 111, 112 and 113. Moreover, the gate electrode structure 160A and the resistor 160B may comprise a sidewall spacer structure 161, for instance comprised of silicon nitride, silicon dioxide and the like. Furthermore, a dielectric cap material 114 may be provided on the polycrystalline semiconductor material 113.

The gate electrode structure 160A and the resistor 160B may be formed on the basis of the layer stack 110 of FIG. 1a. That is, the layer stack 110 of FIG. 1a may be patterned on the basis of sophisticated lithography and etch techniques, thereby providing a first layer stack 110A, which may have appropriate lateral dimensions so as to comply with the requirements of the gate electrode structure 160A. Similarly, a second layer stack 110B may be provided and may have appropriate lateral dimensions corresponding to the requirements for the resistor 160B. It should be appreciated that the patterning of the layer stack 110 of FIG. 1a may typically involve the deposition of further sacrificial materials, such as the dielectric cap layer 114 in combination with other hard mask materials and the like, which may be removed upon forming the gate electrode structure 160A and the resistor 160B. Since the cap layer 114 is used in some approaches, for instance, for incorporating a strain-inducing semiconductor alloy in some of the active regions of the device 100, this layer may still be preserved in this manufacturing stage. Furthermore, if required, a spacer structure 161 may be provided by using any appropriate process technique, such as multi-layer deposition techniques and the like. It should be appreciated that a crystalline status of the layers 112 and 113 may be substantially identical in the gate electrode structure 160A and the resistor 160B since any processes may be performed in the same way for both of these device features.

FIG. 1c schematically illustrates the semiconductor device 100 in a further advanced manufacturing stage. As shown, the transistor 150 may comprise drain and source regions 151 formed in the active region 102A and laterally enclosing a channel region 152. Furthermore, in the embodiment shown, metal silicide regions 153 may be formed in the drain and source regions 151. The gate electrode structure 160A may comprise an additional spacer structure 162, which may be used for defining the lateral offset of the metal silicide regions 153, if provided in this manufacturing stage, and also to define the lateral and vertical dopant profile of the drain and source regions 151. The spacer structure 162 may have any appropriate configuration in terms of the number of spacer elements, any etch stop liners and the like. Moreover, a metal silicide 163 may be formed in the polycrystalline material 113 in order to enhance overall conductivity of the gate electrode structure 160A.

The resistor 160B may comprise a dielectric cap material or a silicidation stop material 116, which may define corresponding contact areas 164B, in which the metal silicide 163 may be provided so as to reduce the contact resistivity of the resistor 160B. Consequently, the mask 116 may basically define the lateral size of the resistor 160B, since the non-silicided polycrystalline semiconductor material 113 formed below the mask 116 may essentially define the resistance value of the resistor 160B, as is also previously discussed. Moreover, the resistor 160B may also comprise the spacer structure 162. The semiconductor device 100 as illustrated in FIG. 1c may be formed on the basis of the following processes. After patterning the gate electrode structure 160A and the resistor 160B, any additional process steps may be applied, for instance for incorporating strain-inducing semiconductor materials in some transistors and the like, followed by implantation process sequences and appropriate masking regimes in order to form the drain and source regions 151 and also in order to establish a desired dopant concentration in the polycrystalline material 113 of the resistor 160B. As discussed above, the material 113 may contribute the main part of the overall resistance value of the resistor 160B, thereby enabling an efficient adjustment of the finally desired resistance value. It should be appreciated that, during the entire process sequence, a significant deterioration of the crystalline state of the material 112 in the resistor 160B may be omitted so that the layer 112 in the resistor 160B and the layer 112 of the gate electrode structure 160A may have substantially the same crystalline state. It should be appreciated that the crystalline state of this layer may change to a certain degree, for instance caused by any high temperature anneal processes, wherein, however, the same crystalline quality may be preserved in the gate electrode structure 160A and the resistor 160B throughout the entire processing due to the avoidance of any deteriorating process steps, such as an amorphization implantation process, as is typically applied in conventional strategies, as discussed above. After any implantation process, high temperature anneal processes may be performed in accordance with device requirements and thereafter the mask 116 may be provided and patterned in order to appropriately define the lateral size of the actual resistor region in the resistor 160B, i.e., by defining the contact areas 164B. It should be appreciated that the mask 116 may be provided in the form of the dielectric cap material 114 (FIG. 1b), if considered appropriate. Next, any appropriate silicidation technique may be applied in order to form the metal silicide materials 153 and 163.

Thereafter, the further processing may be continued by depositing an appropriate interlayer dielectric material or material system and patterning the same so as to receive openings, which may subsequently be filled with a conductive material in order to form contact elements so as to connect to the transistor 150 and the resistor 160B.

FIG. 1d schematically illustrates the semiconductor device 100 according to further illustrative embodiments. As shown, the basic configuration of the transistor 150 may be completed, i.e., the drain and source regions 151 may be formed in the active region 102A. This may be accomplished on the basis of any appropriate implantation and masking regime, as described above. It should be appreciated that, in this manufacturing stage, metal silicide regions may be provided (not shown) in some illustrative embodiments, while, in other strategies, local metal silicide regions may be provided in a later manufacturing stage, i.e., upon forming corresponding contact elements. Furthermore, in the manufacturing stage shown, the crystalline status of the materials 112 in the gate electrode structure 160A and the resistor 160B may be very similar since the material 112 in the resistor 160B may not have experienced any dedicated process for deteriorating, i.e., amorphizing, the crystalline status. Furthermore, the portion of an interlayer dielectric material or material system 120 may be provided, for instance in the form of a first dielectric layer 121, such as a silicon nitride material, in combination with a second dielectric material 122, such as a silicon dioxide material. The interlayer dielectric material or system 120 may be provided on the basis of any well-established process technique. Thereafter, excess material of the material system 120 may be removed, for instance by etching, chemical mechanical polishing (CMP) and the like. In this manner, the polycrystalline material 113 may be exposed, as for instance shown for the resistor 160B, and thereafter an appropriate etch strategy may be applied in order to selectively remove the polycrystalline semiconductor material from the gate electrode structure 160A, while avoiding the removal of at least a significant portion of the material 113 in the resistor 160B. For example, a corresponding etch mask 104 may be provided, while, in other cases, the etch resistivity of the surface of the material 113 may be modified and the like. After the removal of the polycrystalline semiconductor material in the gate electrode structure 160A, any further materials may be deposited, such as a work function adjusting species, as schematically indicated by 166, and an electrode metal, such as an aluminum material, aluminum alloys and the like, may be deposited, as schematically indicated by 167. Consequently, in this replacement gate approach, the resistor 160B may also be efficiently provided on the basis of the polycrystalline material 113 without requiring a dedicated deterioration of the crystal state of the layer 112, which may also result in superior process efficiency since any additional measures for deteriorating the material 112 and/or for redesigning the resistor 160B may be omitted.

As a result, the present disclosure provides manufacturing techniques and semiconductor devices in which a polycrystalline semiconductor material in the form of a silicon material, a silicon/germanium material and the like may be used in combination with a “non-modified” conductive cap material, which may be used in the context of forming sophisticated high-k metal gate electrode structures, since it has been recognized that the resulting resistance values of resistors may be dominated by the polycrystalline semiconductor material rather than by the conductive cap material, even if preserved in a non-deteriorated state. Consequently, precise resistance values may be accomplished without requiring a redesign and on the basis of superior process efficiency.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A semiconductor device, comprising:
a transistor comprising a gate electrode structure, said gate electrode structure comprising a first stack of material layers comprising a high-k gate dielectric material and a metal-containing electrode material formed above said high-k gate dielectric material; and
a resistor comprising a second stack of material layers comprising said high-k dielectric material, said metal-containing electrode material and a polysilicon electrode material formed above said metal-containing electrode material, wherein a crystalline structure of said metal-containing electrode material is substantially identical in said first and second stacks of material layers.

2. The semiconductor device of claim 1, wherein said metal-containing electrode material comprises titanium and nitrogen.

3. The semiconductor device of claim 2, wherein said metal-containing electrode material further comprises aluminum so as to form a titanium aluminum nitride material.

4. The semiconductor device of claim 1, wherein said first stack of material layers comprises said polysilicon electrode material.

5. The semiconductor device of claim 4, wherein said first stack of material layers further comprises a metal silicide formed in a portion of said polysilicon electrode material.

6. The semiconductor device of claim 1, wherein said resistor further comprises a contact area comprised of metal silicide and formed in said second stack of material layers.

7. The semiconductor device of claim 1, wherein said gate electrode structure has a gate length of approximately 50 nm or less.

8. The semiconductor device of claim 1, wherein said metal-containing electrode material has a thickness of approximately 30 nm or less.

9. The semiconductor device of claim 1, wherein said first stack of material layers further comprises an electrode metal formed above said metal-containing electrode material.

10. The semiconductor device of claim 9, wherein said electrode metal comprises aluminum.

11. A method of forming a resistive structure of a semiconductor device, the method comprising:
forming a insulating material layer above a first device region and a second device region, said insulating material layer comprising a high-k dielectric material;
forming a titanium and nitrogen-containing conductive material layer above said insulating material layer;
forming a polycrystalline silicon layer above said titanium and nitrogen-containing conductive material layer; and
forming a gate electrode structure of a transistor above said first device region and a resistor structure above said second device region of said semiconductor device, said gate electrode structure and said resistor structure comprising said insulating material layer, said titanium and nitrogen-containing conductive layer and said polycrystalline silicon layer.

12. The method of claim 11, further comprising preserving a crystalline status of said titanium and nitrogen-containing conductive layer so as to stay substantially identical in said gate electrode structure and said resistor structure.

13. The method of claim 11, wherein forming said titanium and nitrogen-containing conductive material layer comprises forming a titanium aluminum nitride layer.

14. The method of claim 11, further comprising forming a metal silicide in said gate electrode structure and in a contact area of said resistor structure.

15. The method of claim 11, wherein forming said gate electrode structure comprises replacing said polycrystalline layer at least with an electrode metal, while preserving said polycrystalline layer in said resistor structure.

16. The method of claim 11, wherein said resistor structure is formed above an isolation region provided in said second device region.

17. A method, comprising:
forming a resistive structure above an isolation structure of a semiconductor device, said resistive structure comprising a polycrystalline semiconductor material formed above a high-k dielectric material and a metal-containing cap layer; and
adjusting a resistance of said resistive structure without deteriorating a crystalline state of said metal-containing cap layer.

18. The method of claim 17, further comprising forming a gate electrode structure so as to comprise said high-k dielectric material and said metal-containing cap layer.

19. The method of claim 17, wherein forming said resistive structure comprises forming a titanium and nitrogen-containing layer as said metal-containing cap layer.

20. The method of claim 19, wherein forming said titanium and nitrogen-containing layer comprises forming a titanium, aluminum and nitrogen containing layer.
